(19) United States
(12) Patent Application Publication
(10) Pub. No.: US 2015/0357534 A1
(43) Pub. Date: Dec. 10, 2015

(54) Atomic Layer Deposition (ALD) of TiO2 using (Tetrakis(dimethylamino)titanium) TDMAT as an Encapsulation and/or Barrier Layer for ALD PbS

(71) Applicants: The Board of Trustees of the Leland Stanford Junior University, Palo Alto, CA (US); Honda Patents & Technologies North America, LLC, Raymond, OH (US)

(72) Inventors: Neil Dasgupta, Ann Arbor, MI (US); Andrei T. Iancu, Stanford, CA (US); Hitoshi Iwadate, Tokyo (JP); Michael C. Langston, Missouri City, TX (US); Manca Logar, Mountain View, CA (US); Friedrich B. Prinz, Woodside, CA (US); Orlando Trejo, Stanford, CA (US); Shicheng Xu, Stanford, CA (US)

(21) Appl. No.: 14/299,471

(22) Filed: Jun. 9, 2014

(51) Int. Cl. H01L 33/52

(52) U.S. Cl. CPC H01L 33/52; B82Y 20/00

(57) ABSTRACT

A method of encapsulating PbS quantum dots is provided that includes depositing, using atomic layer deposition (ALD), a first layer of TiO₂ on a substrate, depositing, using ALD, a first layer of PbS quantum dots on the first layer of TiO₂, and depositing, using ALD, an encapsulating layer of the TiO₂ on the first layer of TiO₂ and the first layer of PbS quantum dots, where the first layer of PbS quantum dots are encapsulated and separated by the first layer of TiO₂ and the encapsulating layer of TiO₂.

### FIELD OF THE INVENTION

The current invention generally relates to solar cell architectures but can also be applied more broadly to any device that uses PbS quantum dots, including but not limited to devices such as photodetectors and light emitting diodes. More specifically, the invention relates to a method of fabricating PbS quantum dots and a TiO₂ inter-dot barrier material by atomic layer deposition.

### BACKGROUND OF THE INVENTION

Current solar cell architectures use TiO₂ as a junction material. TiO₂ is a common material in photovoltaic designs because of its many beneficial properties. Currently, quantum dots are manufactured in a colloidal solution and deposited on the substrate by spin casting. The dots are separated from each other by the deposition of organic ligands prior to the spin casting process. The ligands are chemically attached to the surface of the dots and serve as both a protective layer and a means to control the distance between individual dots. However, the ligands themselves are not conducting and introduce large electrical resistances between the dots leading to the poor performance of these nanostructures in a wide range of applications.

What is needed is a method of depositing TiO₂ between individual quantum dots. More specifically, what is needed is a method where both PbS quantum dots and TiO₂ inter-dot barrier material are fabricated by atomic layer deposition (ALD) in a manner that preserves the chemical and structural integrity of the individual materials.

### SUMMARY OF THE INVENTION

To address the needs in the art, a method of encapsulating PbS quantum dots is provided that includes depositing, using atomic layer deposition (ALD), a first layer of TiO₂ on a substrate, depositing, using ALD, a first layer of PbS quantum dots on the first layer of TiO₂, and depositing, using ALD, an encapsulating layer of the TiO₂ on the first layer of TiO₂ and the first layer of PbS quantum dots, where the first layer of PbS quantum dots are encapsulated and separated by the first layer of TiO₂ and the encapsulating layer of TiO₂.

According to one aspect of the invention, the size of the PbS quantum dots is controlled by the number of ALD cycles during the PbS quantum dot deposition.

In another aspect of the invention, a second layer of the PbS quantum dots is deposited on the encapsulating layer of the TiO₂, where a second encapsulating layer of the TiO₂ is deposited on the second layer of the PbS quantum dots and the second encapsulating layer of the TiO₂, where stacked layers of the encapsulated and separated PbS quantum dots are formed. Here, more than two layers of the encapsulated and separated PbS quantum dots are formed. Further, the vertical separation of the layers of the encapsulated and separated PbS quantum dots is controlled according to the thickness of the encapsulating layer of the TiO₂.

According to a further embodiment, tetrakis (dimethylamido) Titanium (IV) (TDMAT) is used as an ALD precursor to the TiO₂ deposition.

### BRIEF DESCRIPTION OF THE DRAWINGS

FIG. 1 shows a cross-sectional TEM of p-type Si/ALD TiO₂/ALD ZnO heterojunction solar cell, according to one embodiment of the invention.

FIG. 2 shows IV dashed and dark curves of p-type Si/ALD TiO₂/ALD ZnO heterojunction solar cell, where the excitation source was a 635 nm red laser, according to one embodiment of the invention.

FIG. 3 shows EQE data of p-type Si/ALD TiO₂/ALD ZnO heterojunction solar cell, according to one embodiment of the invention.

FIG. 4 shows PbS quantum dot p-i-n solar cell architecture, according to one embodiment of the invention.

FIG. 5 shows a cross-sectional TEM of PbS quantum dot p-i-n solar cell, according to one embodiment of the invention.

FIG. 6 shows PbS quantum dot solar cell short circuit current vs. PbS cycle number, where the excitation source was a 1550 nm infrared laser, according to one embodiment of the invention.

FIGS. 7a-7d show four different samples fabricated to test the effect of a gradient in size of QDs including: (a) sample with no PbS QDs, (b) sample with same size QDs, (c) sample with a gradient in QDs expected to assist charge extraction, and (d) sample with a gradient in QDs expected to impede charge extraction, according to embodiments of the current invention.

FIG. 8 shows absorption measurements for the four solar cells of FIG. 7 with photon energies from 0.5 to 4 eV, where the samples were deposited on quartz, according to embodiments of the current invention.

FIG. 9 shows the absorption of the four samples of FIG. 7 from 0.5 to 2 eV, according to embodiments of the current invention.

FIG. 10 shows dark I-V measurements for the four solar cells shown in FIG. 7, according to embodiments of the current invention.

FIG. 11 shows EQE measurements for the four solar cells shown in FIG. 7, with photon energies from 1 to 4 eV, according to embodiments of the current invention.

FIG. 12 shows EQE measurements for the four solar cells shown in FIG. 7, with photon energies from 0.6 to 1.1 eV, according to one embodiment of the invention.

FIG. 13 shows IQE measurements for the four solar cells shown in FIG. 7, with photon energies from 0.6 to 1 eV, according to embodiments of the invention.

FIG. 14 shows the average IQE from 0.6 to 1 eV for the four solar cells shown in FIG. 7, according to embodiments of the invention.

FIG. 15a-15b show band diagrams for (a) correct and (b) incorrect gradient PbS QD solar cells shown in FIG. 7, according to embodiments of the current invention.

FIG. 16 shows a flow diagram for encapsulating PbS quantum dots, according to one embodiment of the invention.

### DETAILED DESCRIPTION

One of the current embodiments of the invention is a method of fabricating a functioning all-ALD PbS QD solar cell. In one example, tests are provided to determine whether or not a gradient in QDs may assist with charge carrier extraction. According to the invention, an ALD reactor was constructed which demonstrated the ability to deposit PbS QDs as well as different barriers to make QD matrix structures. It was also shown the optical band gap of the ALD PbS QDs were able to be tuned by their size. Further, p-i-n structure ALD PbS QD solar cells were fabricated and characterized by TEM, current-voltage (I-V), external quantum efficiency (EQE), internal quantum efficiency (IQE), and absorption measurements, to confirm device performance, as well as test the effect of graded layers of QDs.

The current invention uses TiO₂ as the material disposed between and around individual PbS quantum dots (QD), where the PbS QDs and the TiO₂ inter-dot barrier material are fabricated by atomic layer deposition (ALD). The chemistry of the ALD deposition process makes it very difficult to both deposit PbS dots and provide a barrier material between them without significantly damaging the chemical composition and morphology of the dots. The current invention provides one solution to that problem.

According to one embodiment, a p-i-n type structure is provided with p-type Si as the “p” region, an ALD PbS QD/TiO₂ matrix as the “i” region, and ALD ZnO as the “n” region, the structure was first investigated without embedded PbS QDs to confirm photovoltaic performance. The “p” and “n” regions used in this device, p-type silicon and ZnO respectively, can be used to make a heterojunction solar cell, according to one embodiment of the invention.

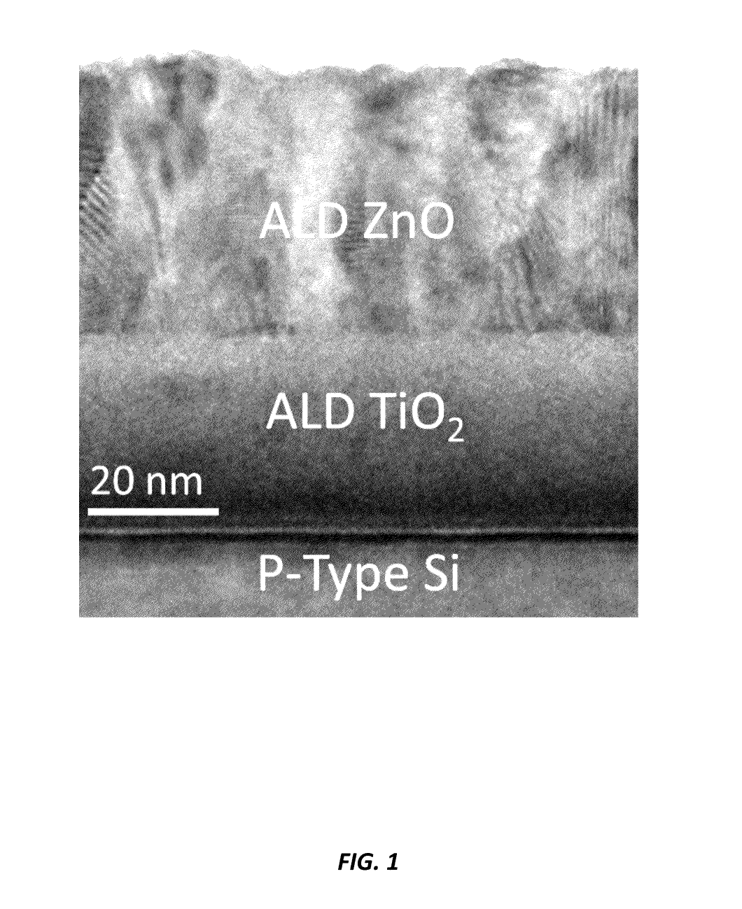

In one exemplary embodiment, the structure is a p-type Si/ALD ZnO solar cell with a thin TiO₂ layer added in the middle. To study this structure, 300 cycles corresponding to approximately 18 nm of TiO₂ and 350 cycles, corresponding to approximately 35 nm of ALD ZnO, were deposited on 2-6 Ω-cm boron doped (100) 500 μm thick silicon wafers. A cross-sectional TEM image of this structure is shown in FIG. 1, and confirms the as expected morphology of the structure.

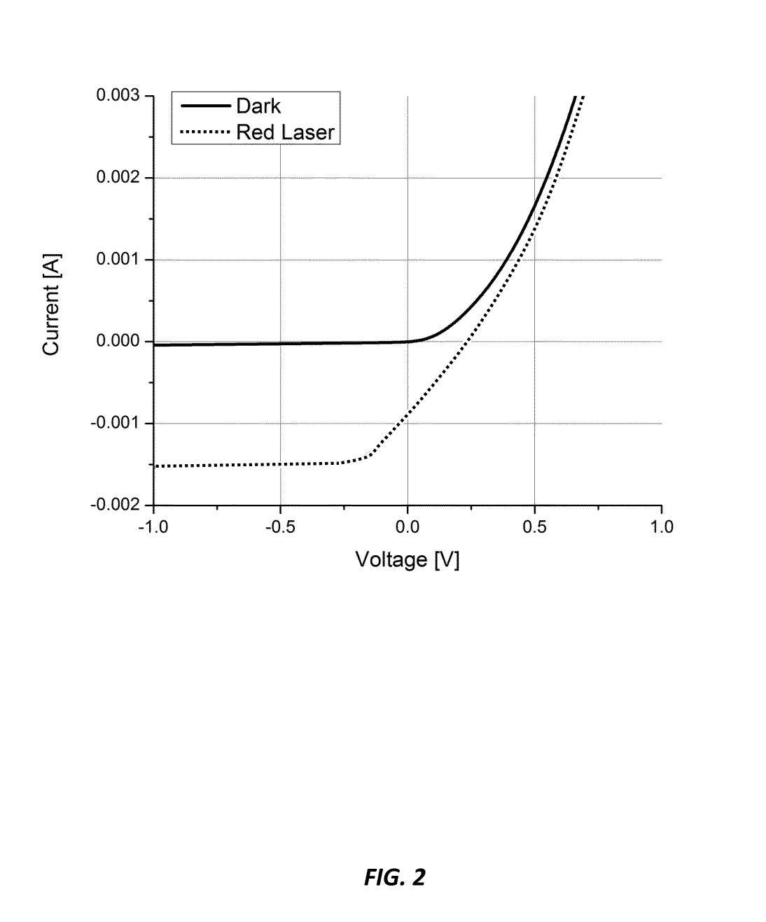

After deposition was completed an aluminum electrode was evaporated on the backside of the Si wafer to make a back contact. Using lithography, a top aluminum electrode was evaporated in a serpentine pattern to allow for current collection out of the device, while minimizing light shadowing. Once the device was fabricated, light and dark IV sweeps were performed to confirm the rectifying behavior as well as light response. FIG. 2 shows the light and dark I-V curves for the p-type Si/ALD TiO₂/ALD ZnO heterojunction solar cell. The light source used was a 635 nm red laser (Thor Labs). It should be noted that the y-axis of the I-V plot shows current and not current density as the exact region of charge extraction was not well defined in these experiments.

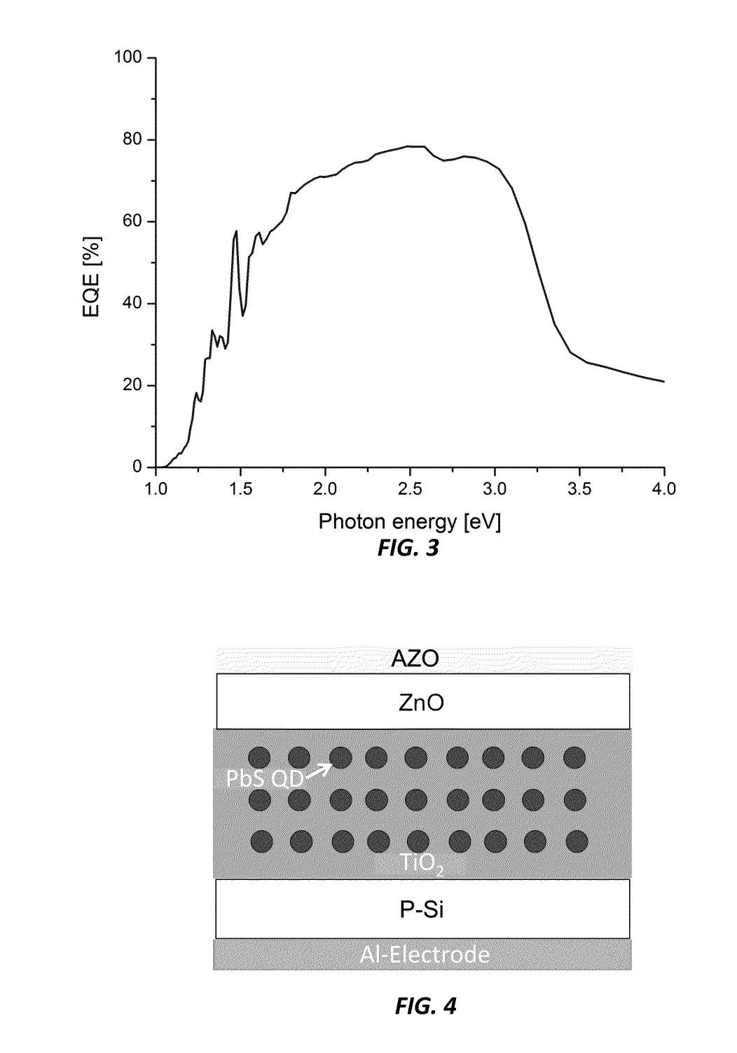

From FIG. 2, it can be seen that the dark curve shows the expected rectifying behavior. Furthermore, the DASHED curve shows the predicted downward shift in the IV curve validating PV performance. Next an EQE measurement was taken to quantify how efficiently incident photons were converted into electrons and extracted out of the solar cell. FIG. 3 shows the EQE for the aforementioned p-type Si/ALD TiO₂/ALD ZnO solar cell. The device shows improved EQE performance with greater than 60% EQE in the visible, as well as 15-20% in the UV region. Normally in a Si cell, EQE in the UV region is very poor due to the extremely short absorption length for UV photons in Si, which are not extracted efficiently due to surface recombination. The UV EQE in this cell is due to the ALD ZnO, which has a large 3.4 eV bandgap, and therefore is another added benefit of using ZnO as the n-region in this device.

As the p-type Si/ALD TiO₂/ALD ZnO solar cell showed good IV and EQE performance, next uniform ALD PbS QD layers were inserted into the TiO₂ to confirm carrier extraction from the PbS QDs.

Turning now to the ALD PbS QD p-i-n structure solar cells with uniform QD size, initially p-i-n structure PbS QD solar cells with uniform QD layers were fabricated to verify successful charge extraction from the PbS QDs. The solar cells were the p-type Si/ALD ZnO structure, with PbS QD/TiO₂ matrix structures inserted in the middle, resulting in the desired p-i-n structure. Samples were made with “i” regions using 10, 20, 30, and 40 cycles of PbS embedded in TiO₂. FIG. 4 shows a schematic of the PbS QD p-i-n solar cell architecture. It should be noted that while this sample only shows three layers of QDs, in actuality the number of layers varies from 5 for QDs of 40 cycles of PbS, to 20 for QDs of 10 cycles of PbS.

For these examples a special measurement system was developed to measure these samples in situ, therefore a metal top electrode could not be deposited, and rather aluminum doped ZnO (AZO) was deposited by ALD to make a top contact.

The samples were measured in situ to assist with repeatability and to avoid oxidation of the ALD PbS QDs. It is also important to note that in these test bed architectures, carriers in the visible wavelengths are created by both the Si and the PbS QDs. Therefore, to verify a photocurrent from the PbS QDs, and also test the hypothesized effect of a gradient in QDs, carriers created with photon energies less than the band gap of Si (˜1.12 eV) are investigated.

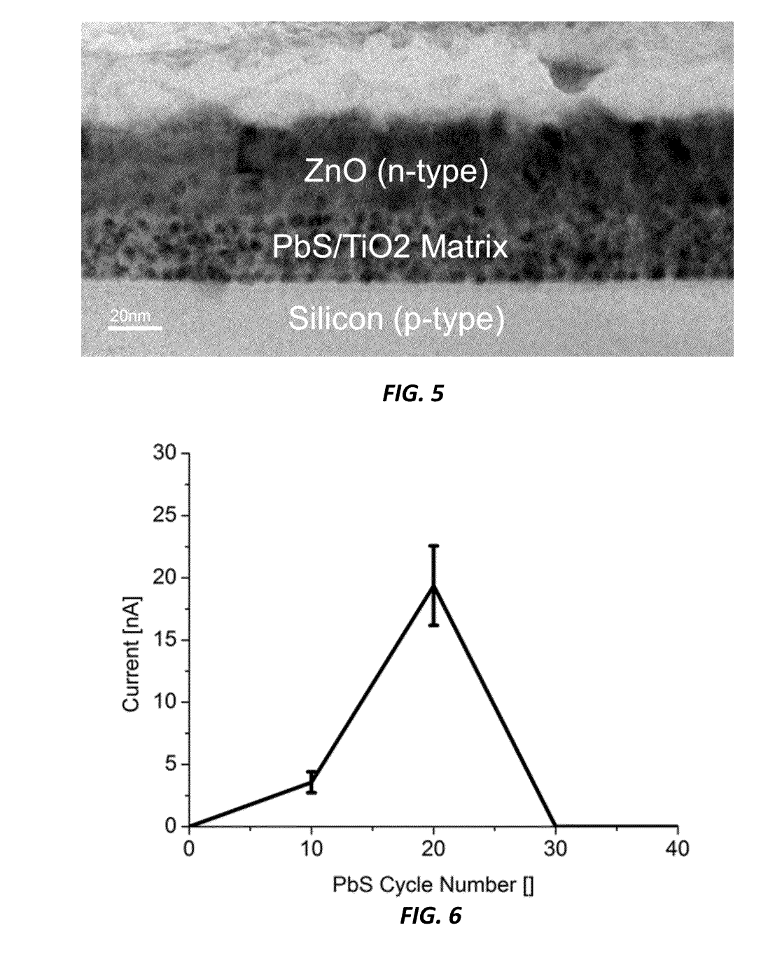

FIG. 5 shows a cross-sectional TEM micrograph of a p-i-n structure PbS quantum dot solar cell. This sample used 20 cycles of PbS with 10 layers. It should also be noted that the PbS/TiO₂ region in this sample was too thick to show a single layer of quantum dots, therefore in this image several layers of quantum dots may be superimposed. However this TEM image confirms the expected microstructure of the ALD PbS QD solar cell.

FIG. 6 shows the short circuit current for the quantum dot solar cell as a function of cycle number and thus quantum dot size. The excitation source for these measurements was a (1550 nm) IR laser, which is below the silicon band gap, and thus should represent a current from the PbS quantum dots. From FIG. 6 it is shown that only the smaller and thus larger band gap quantum dots of 10 and 20 cycles of PbS show a infrared photocurrent. This may be attributed to the decrease in barrier height for injection of electrons into the ZnO as the PbS confinement increases.

This architecture demonstrates the successful fabrication of a working all ALD PbS QD solar cell. The infrared photocurrents for the 10 and 20 cycle PbS samples also confirm successful extraction of photogenerated carriers from the PbS QDs. Now that successful performance of the ALD PbS QD solar cell has been validated, next a test to the hypothesis that a gradient in QD size may assist with charge extraction in the PbS QDs is provided.

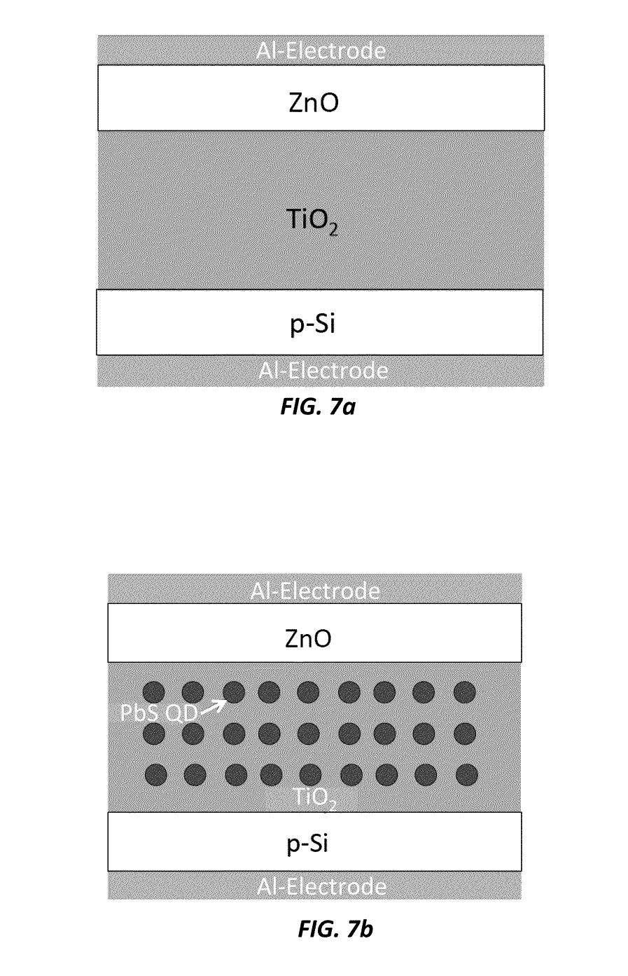

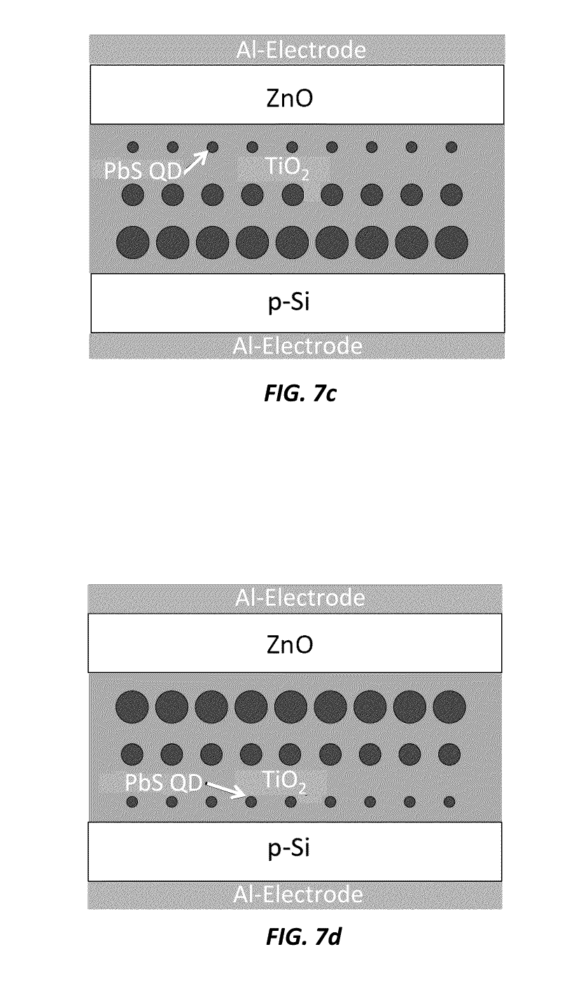

To test the effect of a gradient in QD size, four samples were fabricated and directly compared. The samples included a control (no PbS), a sample with the same size PbS QDs, a sample with a correct gradient which is speculated to assist with charge extraction, and a incorrect gradient which is speculated to impede charge extraction. FIGS. 7a-7d show diagrams of the four different samples which were fabricated.

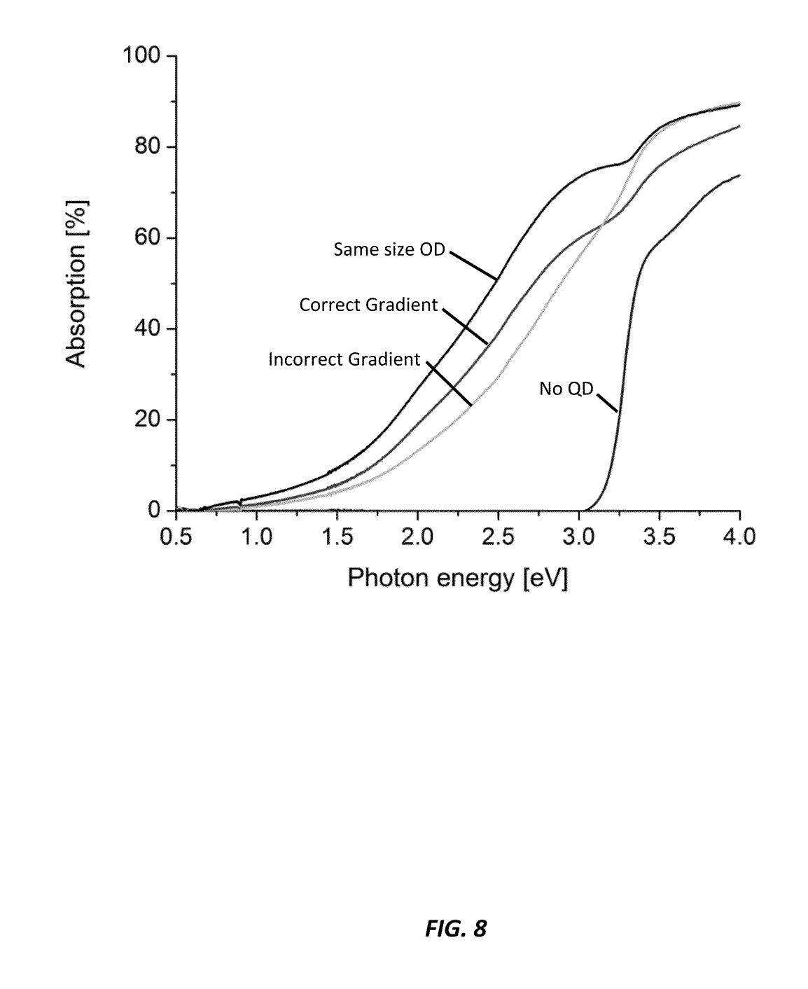

After the sample set was decided, samples were fabricated on both Si and quartz in the same ALD run. This allows for both absorption as well as EQE measurements to be performed with the same sample. The absorption measurements are necessary to find an internal quantum efficiency (IQE). IQE should directly be related to the extraction efficiency of carriers in the solar cell, and thus may be used to validate the hypothesized effect of QD gradients. FIG. 8 shows absorption measurements for the four separate samples from 0.5 to 4 eV.

From FIG. 8 it is apparent the control sample with no PbS QDs shows almost no absorption in the visible, and begins to absorb around 3 eV, which agrees well with the approximately 3.4 eV band gap of ZnO and TiO₂. The PbS QD samples absorption begin in the near infrared and increases into the visible, showing approximately 10-60% in the visible.

The absorption is similar between the QD samples, however it can be seen that the same size QD sample shows the highest absorption, while the correct gradient sample shows the next most, and the incorrect gradient sample shows the least absorption. As the gradient effect will be verified with sub-silicon band gap absorption, it is important to look at the absorption of the samples in this region.

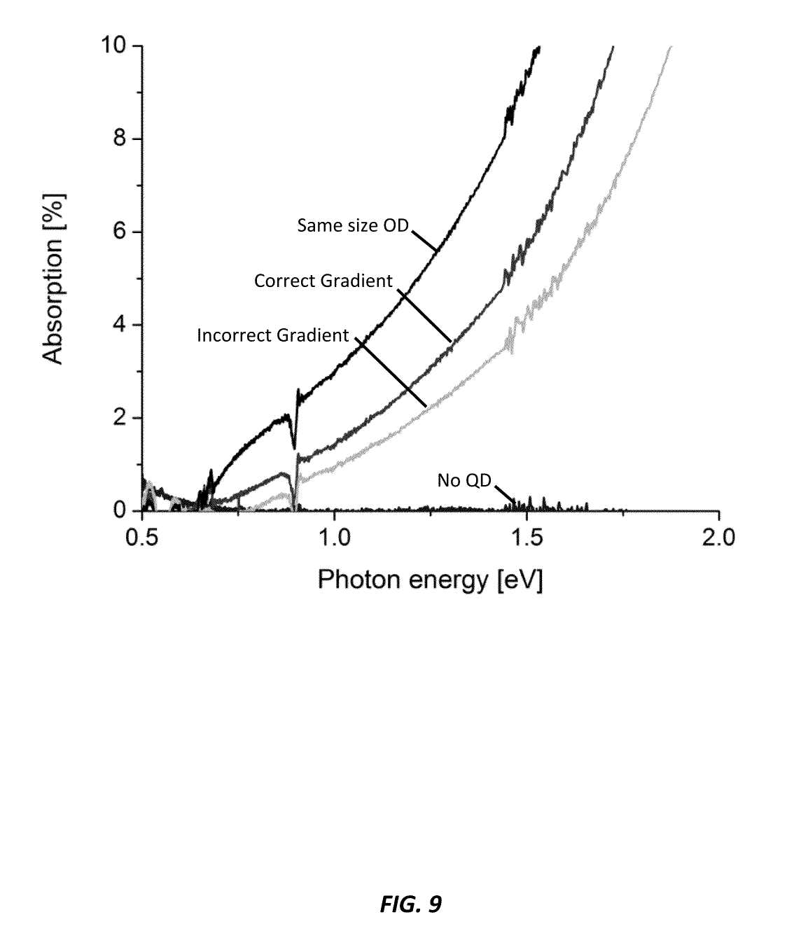

From FIG. 9 it can be seen that the absorption for the control shows almost no absorption in this region, which is expected, as there are no QDs in the sample and Qz, TiO₂, and ZnO do not absorb in this regime. The correct and incorrect gradient samples have very similar absorption amounts of approximately 0-3% in the infrared, while the same size QD sample shows slightly larger absorption of approximately 0-5% in the same region.

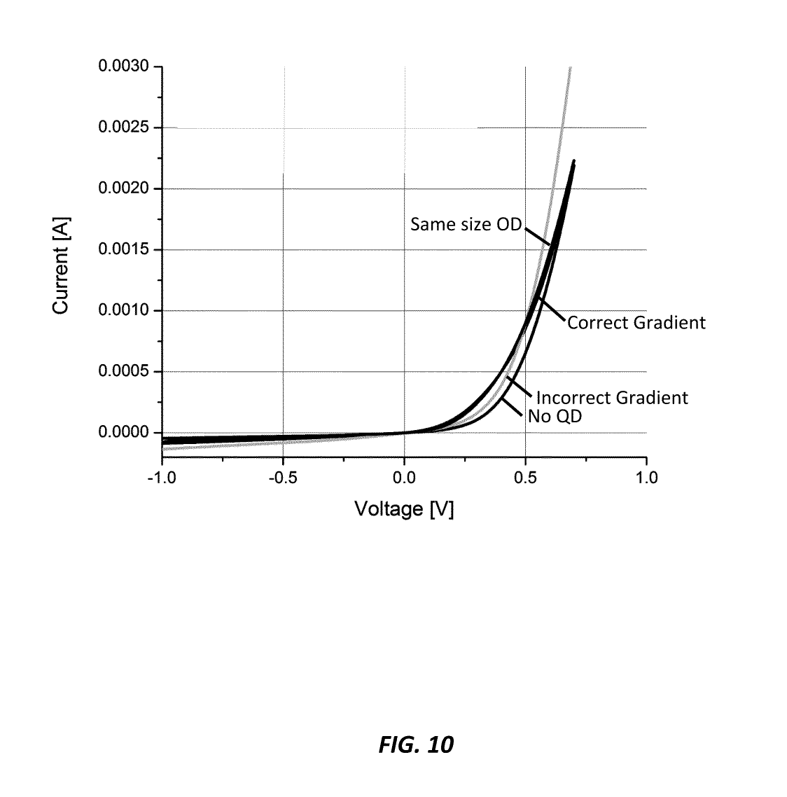

Next dark I-V curves were performed on all four samples to verify rectifying behavior. These measurements were done on the Si samples that were in the same chamber as the quartz, and thus their sample structures should be identical. FIG. 10 shows the dark I-V curves for the four solar cell samples.

From FIG. 10, it can be seen that rectifying behavior is observed for all samples. The correct gradient, same size QD, and no QD samples show similar I-V behavior, while the incorrect gradient appears to show similar rectifying behavior but with a slightly lower shunt resistance. This can be seen by the larger reverse bias current in the incorrect gradient sample. The degree of shunting varied from sample to sample and was usually due to small pinholes or percolation pathways through the thin film solar cells. However, shunt resistances in all samples were fairly high, and the relatively small variations in shunt resistance between samples should not drastically change the PV performance of the solar cells.

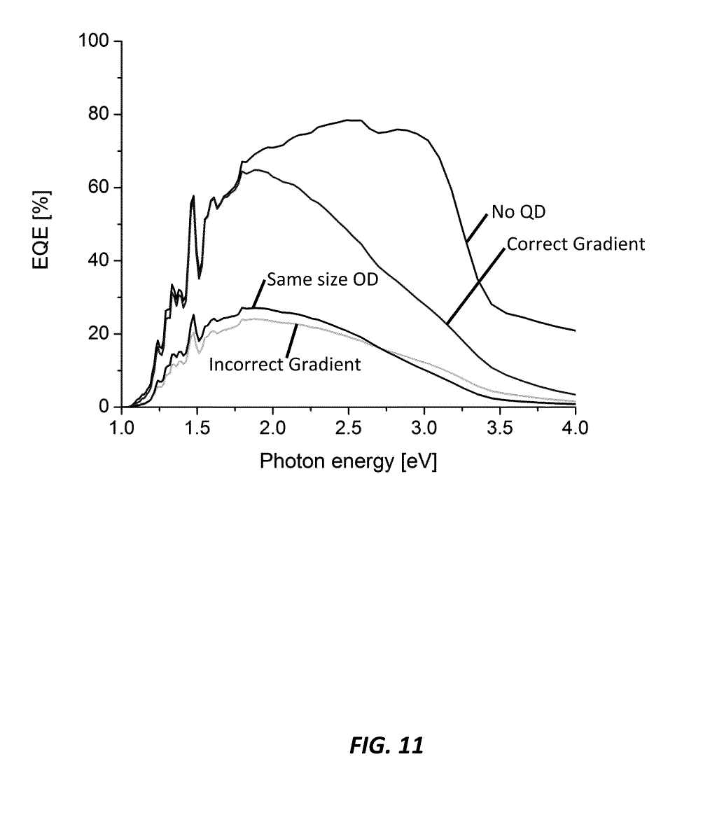

Next, EQE measurements were performed on the samples. FIG. 11 shows the EQE measurements for the four samples shown in FIG. 7.

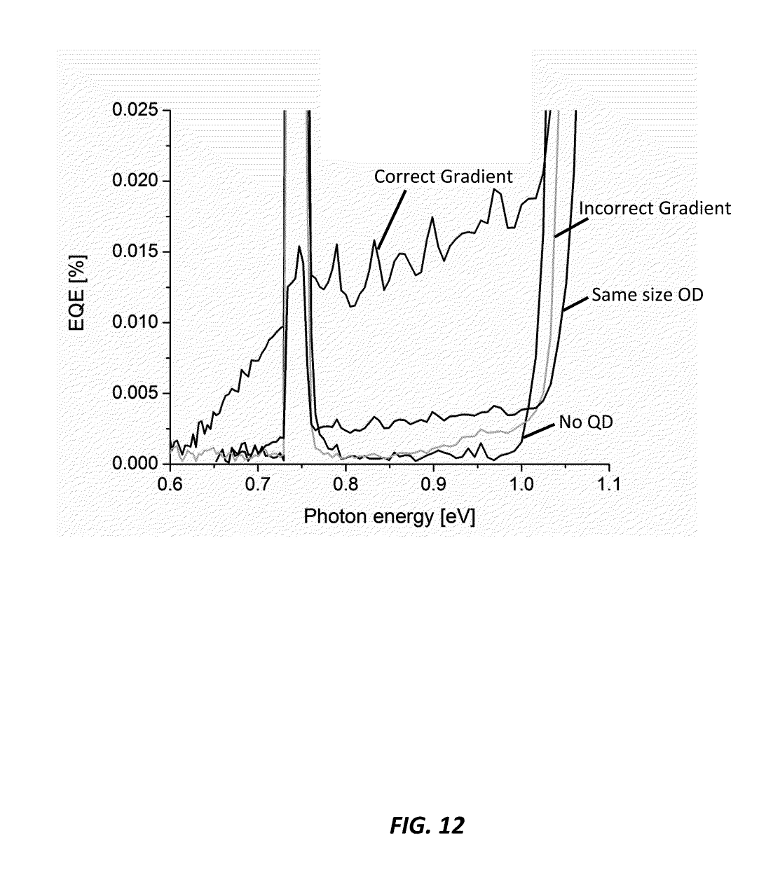

From FIG. 12 it can be seen that the control sample, with no QDs shows the highest EQE in the visible and UV regions. This is due to the fact that in the control, nearly all of the absorption is in the Si, which is very high quality and thus results in a very high charge extraction. The samples with QDs have approximately 20-30% absorption in the visible, and will only have the same EQE as the control if the charge extraction efficiency is the same for the PbS QDs and the silicon. The charge extraction should be lower in the PbS QDs as the excitons created in PbS QDs must tunnel through several layers, and may also have more interfaces and defects when compared to the control sample.

Looking at the QD samples, it can be observed that the correct gradient shows the highest EQE in the visible and UV, showing nearly the same EQE as the control in lower photon energies of the visible, however the EQE falls significantly for photon energies above 1.8 eV. This is most likely due to the fact that for the shorter wavelengths a significant of light is absorbed near the interface of the TiO₂/PbS matrix and the ZnO, and holes may have a difficult time tunneling through the entire TiO₂/PbS matrix layer to get to the p-type Si and get extracted. The same size QD sample shows the next highest EQE, however it is significantly lower than the correct gradient in both the visible and UV. Lastly the incorrect gradient sample shows the lowest EQE of all the samples. Importantly, since the correct and incorrect gradient samples have similar absorption in the visible it suggests charge extraction is higher in the correct gradient sample. However, since the visible wavelengths are absorbed in both the silicon and the PbS QDs, it is difficult to identify the source of the photocurrent in this wavelength regime. Therefore, to isolate the current solely coming from the PbS QDs, it is necessary to examine the currents from photon energies lower than the band gap of Si, which is approximately 1.1 eV. FIG. 12 shows EQE measurements from 0.6 to 1.1 eV.

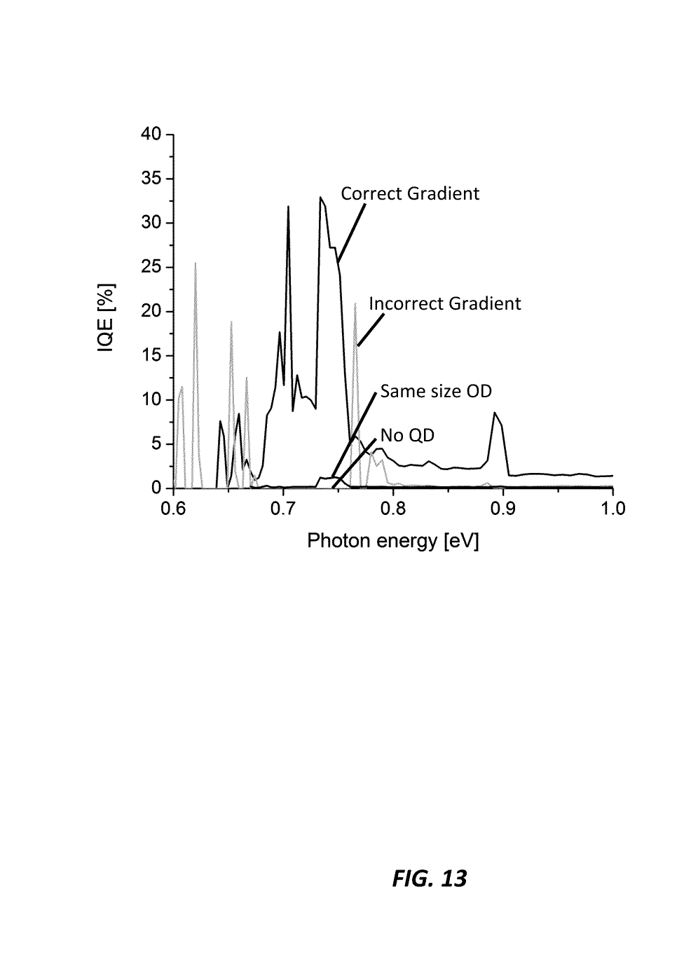

From FIG. 12 it can be seen that the EQE for the sample with no QDs drops off sharply to near 0 at 1 eV. The correct gradient shows the most current in the infrared, showing between 0.005-0.02% EQE between 0.7 and 1 eV. It should be noted that the EQE spike at 0.75 eV is an artifact of calibration issues with the detector, and does not describe any of the physics occurring in the device. The next highest EQE in this region is the same size QD sample, which shows low 0.001-0.004% infrared current between 0.7 to 1 eV. And lastly, the incorrect gradient sample shows approximately 0.0025% EQE at 1 eV, which drops to 0 by approximately 0.9 eV. This data suggests that the correct gradient sample yields the most current from the PbS QDs. However, to more directly measure the charge extraction efficiency, the IQE was calculated using the EQE and absorption data. FIG. 13 shows the IQE for the four samples from 0.6 to 1 eV, according to embodiments of the invention.

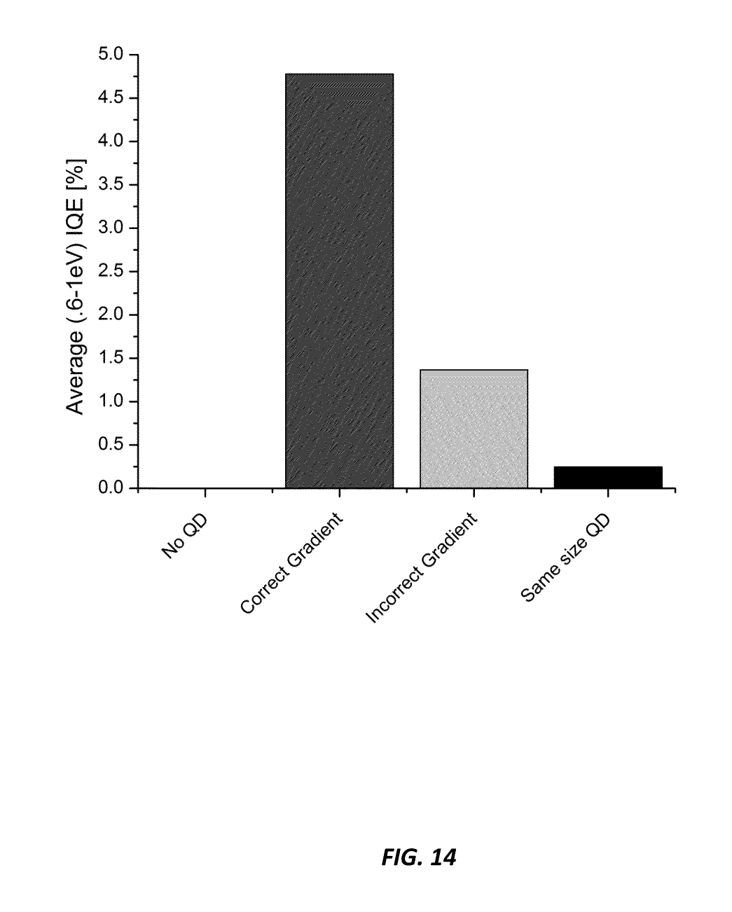

From FIG. 13 the control sample shows no observable IQE in the infrared. This again is as expected, as the EQE was also negligible for the control in this region. Next, the correct gradient shows the highest IQE in this energy range, with approximately 1-10%. The spike at 0.75 eV may be partly due to the spike in EQE as well as absorption discussed previously. Next, the incorrect gradient shows a 0.2-4% IQE, which is significantly smaller than the correct gradient. It should be noted that some of the spikes for the incorrect gradient IQE measurement are also likely due to spikes in the EQE and absorption. Finally, the same size QD sample shows the lowest IQE of approximately 0.1 to 0.3%. To more directly compare the IQEs and thus charge extraction of these samples, the IQE was averaged from 0.6 to 1 eV and is shown in FIG. 14.

As can be seen from FIG. 14, the IQE is 0 for the sample with no QDs, which should be expected. The correct gradient sample shows the highest IQE of approximately 4.8%, while the incorrect gradient shows a much smaller approximately 1.4% IQE. Lastly, the same size QD sample shows the lowest IQE of approximately 0.25%.

Therefore, FIG. 14 validates the hypothesis that a gradient of QD size may assist with charge extraction efficiency, as the correct gradient shows an increase in IQE of approximately 340% when compared to the incorrect gradient sample.

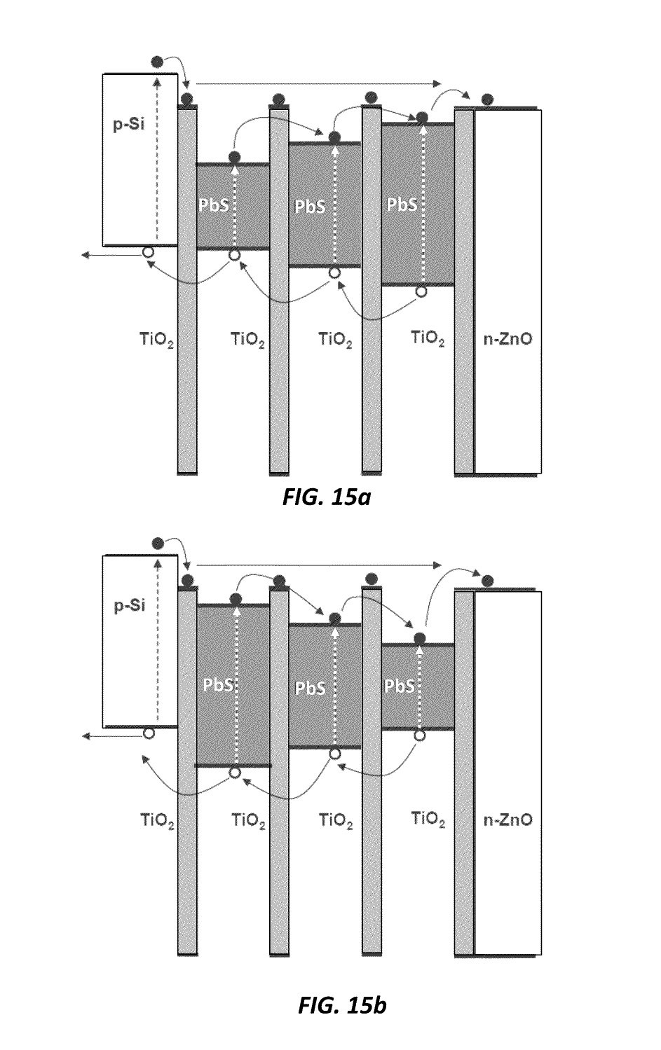

While this result suggests that a charge polarization effect may be leading to an increase in charge extraction efficiency, it is important to acknowledge that other effects may be present. For example, the band structure diagrams of the correct and incorrect gradient structures may reveal insights, which offer alternative explanations for their different charge extraction efficiencies. FIGS. 15 (a) and 15(b) show the band structures for the correct and incorrect gradient samples respectively. From this figure it is clear that the correct gradient structure leads a thermodynamic driving force for hole extraction, while the incorrect gradient structure will lead to a thermodynamic driving force for electron extraction. Since it is speculated that the currents for these structures are limited by hole extraction due to the large valence band offsets of PbS and TiO₂, this increased driving force for hole extraction in the correct gradient structure may explain the higher IQE for this sample.

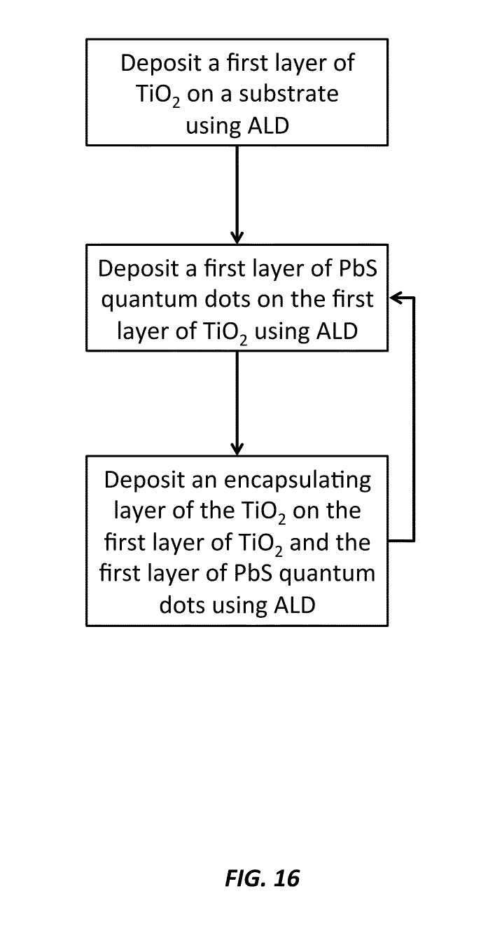

In order to fabricate encapsulated PbS quantum dots, the current invention uses atomic layer deposition (ALD) to deposit a first layer of TiO₂ on a substrate, then depositing a first layer of PbS quantum dots on the first layer of TiO₂ using ALD, and depositing an encapsulating layer of the TiO₂ on the first layer of TiO₂ and the first layer of PbS quantum dots using ALD, where the first layer of PbS quantum dots are encapsulated and separated by the first layer of TiO₂ and the encapsulating layer of TiO₂. FIG. 16 shows a flow diagram of this process, according to one embodiment, where shown is the encapsulation process of the PbS quantum dots can be iteratively applied.

According to one embodiment, the size of the PbS quantum dots is controlled by the number of ALD cycles during the PbS quantum dot deposition.

In another embodiment of the invention, a second layer of the PbS quantum dots is deposited on the encapsulating layer of the TiO₂, where a second encapsulating layer of the TiO₂ is deposited on the second layer of the PbS quantum dots and the second encapsulating layer of the TiO₂, where stacked layers of the encapsulated and separated PbS quantum dots are formed. Here, more than two layers of the encapsulated and separated PbS quantum dots are formed. Further, the vertical separation of the layers of the encapsulated and separated PbS quantum dots is controlled according to the thickness of the encapsulating layer of the TiO₂.

In one embodiment, tetrakis (dimethylamido) Titanium (IV) (TDMAT) is used as a precursor to allow for deposition of TiO₂ on PbS QDs without unintentionally damaging or doping the PbS.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example, the same ALD TiO₂ and PbS QD layer structure could be applied as the absorbing layer in a photodetector device architecture where the PbS QD size could be varied, as specified in the invention, to change the wavelength of the detected light. Similarly, the ALD TiO₂ and PbS QD layer structure could be applied within the emission layer of a light emitting diode architecture such that the emission wavelength spectrum of the device could be controlled by varying the size distribution of the PbS quantum dots, as specified in the invention.

All such variations are considered to be within the scope and spirit of the present invention as defined by the following claims and their legal equivalents.

1. A method of encapsulating a size gradient of PbS quantum dots in a solar cell, comprising:
a. depositing, using atomic layer deposition (ALD), a first layer of TiO₂ on a substrate;
b. depositing, using said ALD, a first layer of PbS quantum dots on said first layer of TiO₂;
c. depositing, using said ALD, a first encapsulating layer of said TiO₂ on said first layer of TiO₂ and said first layer of PbS quantum dots, wherein said first layer of PbS quantum dots are encapsulated and separated by said first layer of TiO₂ and said first encapsulating layer of TiO₂;
d. depositing, using said ALD, subsequent layer of said PbS quantum dots on said first encapsulating layer, wherein said subsequent layer of said PbS quantum dots is smaller than said first layer of said PbS quantum dots, wherein a size of said PbS quantum dots is controlled according to a number of ALD cycles during said PbS quantum dot deposition;
e. depositing, using said ALD, a subsequent encapsulating layer of said TiO₂, wherein a vertical separation of said PbS quantum dots is controlled according to a thickness of each said encapsulating layer of said TiO₂, wherein each said subsequent layer of said PbS quantum dots is smaller than a previous said subsequent layer of said PbS quantum dots, wherein each said subsequent layer of said PbS quantum dots is encapsulated by another said subsequent layer of said TiO₂, wherein an encapsulated size gradient of said PbS quantum dots is formed;
f. depositing, using lithography, a top electrode; and
g. depositing, using lithography, a bottom electrode, wherein a size gradient PbS QD solar cell is formed.

2. The method of encapsulating PbS quantum dots of claim 1, wherein the size of the said PbS quantum dots is controlled by the number of ALD cycles during said PbS quantum dot deposition.

3. The method of encapsulating PbS quantum dots of claim 1, wherein a second layer of said PbS quantum dots is deposited on said encapsulating layer of said TiO₂, wherein a second said encapsulating layer of said TiO₂ is deposited on said second layer of said PbS quantum dots and said second encapsulating layer of said TiO₂, wherein stacked layers of said encapsulated and separated PbS quantum dots are formed.

4. The method of encapsulating PbS quantum dots of claim 3, wherein more than two layers of said encapsulated and separated PbS quantum dots are formed.

5. The method of encapsulating PbS quantum dots of claim 3, wherein the vertical separation of said layers of said encapsulated and separated PbS quantum dots is controlled according to the thickness of said encapsulating layer of said TiO₂.

6. The method of encapsulating PbS quantum dots of claim 1, wherein tetrakis (dimethylamido) Titanium (IV) (TDMAT) is used as an ALD precursor to said TiO₂ deposition.
